(19) United States
(12) Patent Application Publication
(10) Pub. No.: US 2010/0154880 A1
(43) Pub. Date: Jun. 24, 2010

(54) DYE-SENSITIZED SOLAR CELL, ANODE THEREOF, AND METHOD OF MANUFACTURING THE SAME

(75) Inventors: Chun-Chi LAI, Taipei City (TW); Yu-Chou Chao, Taipei City (TW); Wen-Hsien Ho, Keelung City (TW); Jui-Chi Lin, Tu-Chen City (TW); Chih-Hao Chen, Taipei City (TW)

Correspondence Address: RABIN & Berdo, PC, 1101 14TH STREET, NW, SUITE 500, WASHINGTON, DC, 20005, US

(73) Assignee: TAIWAN TEXTILE RESEARCH INSTITUTE, Tu-Chen City (TW)

(21) Appl. No.: 12/346,798

(22) Filed: Dec. 30, 2008

(30) Foreign Application Priority Data
Dec. 22, 2008 (TW) 97150094

(51) Int. Cl. H01L 31/0224; B05D 5/12

(52) U.S. Cl. 136/256; 427/77

(57) ABSTRACT

A dye-sensitized solar cell (DSSC), anode thereof, and method of manufacturing the same are disclosed. The anode has a titanium dioxide layer mixed with a desired ratio of carbon black nanoparticles to increase the conductivity of the anode. Thereby, the conversion efficiency of the solar energy to electricity for the DSSC is effectively improved.

### RELATED APPLICATIONS

This application claims priority to Taiwan Application Serial Number 97150094, filed Dec. 22, 2008, which is herein incorporated by reference.

### FIELD OF THE INVENTION

This invention relates generally to a solar cell, and more particularly, to a dye-sensitized solar cell (DSSC), an anode electrode thereof, and a method of manufacturing the same.

### BACKGROUND OF THE INVENTION

Since people raise the environmental awareness and other petroleum-related energies are going to exhaust, it is indeed necessary to develop a new and safe energy. A new energy must satisfy at least two requirements for worth developing, one of which is rich in reserves and difficultly exhausted, and the other of which is safe, clean, and friendly to human beings and nature environment. Regenerative energy, for example, solar energy, wind power, water power and so on, can satisfies the above two requirements. Besides, Taiwan lacks natural energy resources, and more than 90% of the required energy must be imported from other countries. However, Taiwan has enough sunlight and more insolation due to its location in the subtropical zone. It is advantageous to research and develop the solar energy in Taiwan, and the electric power converted by the solar energy is beneficial to save energy and environmental protection.

Utilizing solar cells (also called photovoltaic devices) is a direct way to convert the solar energy to energy. Nowadays, silicon (Si) semiconductor materials are utilized to produce most of commercialized solar cells. Si-based semiconductor materials are divided to single-crystal, poly-silicon, amorphous Si and so on according to the Si crystal states. The solar cells fabricated by using single-crystal Si have higher and stable energy conversion efficiency but cost expensively. The solar cells fabricated by using amorphous Si have lower energy conversion efficiency and shorter lifespan. Therefore, the dye-sensitized solar cell (DSSC) fabricated by organic materials such as polymers are more important to the academic and industrial circles.

The DSSC is also known as “Gratzel cell”, which is firstly invented by Michael Gratzel and Brian O'Regan of Swiss Federal Institute of Technology (École Polytechnique Fédérale de Lausanne) in 1991, and this research is titled as “A low-cost, high-efficiency solar cell based on dye-sensitized colloidal TiO₂ films”, published on Nature Vol. 353, No. 6346, pages 737-740 (1991).

The DSSC includes a transparent substrate having a titanium dioxide layer with a dye layer coated thereon, and the dye-sensitized titanium dioxide layer is the key technology for developing the DSSC. Under the light irradiation, electrons are injected into the dye absorbed on the titanium dioxide layer, transferred to the conduction band of the titanium dioxide layer, and then collected by the backward contact and brought out by outside circuits, so as to generate photocurrent. The titanium dioxide layer mainly absorbs the ultraviolet (UV) light, and its optoelectrical conversion efficiency can be effectively increased by absorbing the dye layer thereon, since the dye layer with higher molar extinction coefficient serves as a photosensitizer, absorbs other long wavelength light and reduces the length of electron path. In addition, to prevent the recombination of free electrons with the oxidized dye, the electrolyte of the DSSC includes redox couple of iodide (I⁻) and triiodide (I₃⁻), so as to quickly reduce the holes generated by the dye, thereby keeping the DSSC continuously operating.

In addition to the dye layer, various photo-catalyst, for example, transition metals, light metals, rare earth metals and so on, are mixed into the titanium dioxide to facilitate the separation the photo-generated electron-hole pairs (excitons), thereby enhancing the optoelectrical conversion efficiency of the titanium dioxide. However, that brings less significantly improved effect but more cost.

Hence, it is necessary to provide a photo-catalyst with better optoelectrical conversion efficiency applied in the anode electrode of the DSSC, so as to address the issues of the prior photo-catalysts related to less significantly improved effect but more cost and so on.

### SUMMARY OF THE INVENTION

Accordingly, it is an aspect of the present invention to provide an anode electrode of a DSSC and a method of manufacturing the same, which includes the anode electrode having a titanium dioxide layer mixed with a desired ratio of carbon black nanoparticles. The less and environmentally friendly dye can increase conductivity of the anode, thereby effectively improving the conversion efficiency of the solar energy to electricity for the DSSC.

It is another aspect of the present invention to provide a DSSC, which includes an anode electrode having a carbon black-mixed titanium dioxide layer. The less and environmentally friendly dye can increase conductivity of the anode, thereby effectively improving the conversion efficiency of the solar energy to electricity for the DSSC.

According to the aforementioned aspect of the present invention, an anode electrode of a DSSC is provided. The anode electrode may include a transparent substrate, a carbon black-mixed titanium dioxide layer and a dye layer. The carbon black-mixed titanium dioxide layer may be disposed on the transparent substrate, and the dye layer may be disposed on the titanium dioxide layer. The titanium dioxide nanoparticles may have an anatase phase, and they may have a specific surface area of, for example, to 90 m²/g to 250 m²/g. The carbon black nanoparticles may have an average diameter of, for example, 20 nanometers (nm) to 100 nm, and a weight ratio of the carbon black nanoparticles to the titanium dioxide nanoparticles may be, for example, 1:10 to 1:10000.

In an embodiment of the present invention, the dye may include but not be limited in, for example, a ruthenium complex dye or mercurochrome dye.

According to another aforementioned aspect of the present invention, a method of manufacturing an anode electrode of a DSSC is provided. First of all, a titanium alkoxide, carbon black nanoparticles and an acid may be mixed to perform a sol-gel reaction, so as to form a carbon black-mixed titanium dioxide sol-gel, in which the titanium dioxide sol-gel may include anatase-phase titanium dioxide nanoparticles with a specific surface area of, for example, to 90 m²/g to 250 m²/g; the carbon black nanoparticles may have an average diameter of, for example, 20 nm to 100 nm; and a weight ratio of the carbon black nanoparticles to the titanium dioxide nanoparticles may be, for example, 1:10 to 1:10000. Next, the carbon black-mixed titanium dioxide sol-gel may be coated on a transparent substrate, so as to form a carbon black-mixed titanium dioxide layer. Later, a dye layer is formed on the carbon black-mixed titanium dioxide layer.

In an embodiment of the present invention, the titanium alkoxide may be, for example, titanium isopropoxide, and the acid may be, for example, nitric acid, hydrochloric acid or acetic acid.

In an embodiment of the present invention, the sol-gel reaction may further include to perform a condensation reaction, so as to form a precursor mixed with the carbon black nanoparticles from the titanium alkoxide, the carbon black nanoparticles and the acid. Subsequently, the precursor mixed with the carbon black nanoparticles is subjected to perform a high-temperature and high-pressure reaction, so as to form the carbon black-mixed titanium dioxide sol-gel.

In an embodiment of the present invention, the sol-gel reaction may further include to perform a condensation reaction, so as to form a precursor from the titanium alkoxide and the acid. Subsequently, the precursor is added with the carbon black nanoparticles and subjected to perform a high-temperature and high-pressure reaction, so as to form the carbon black-mixed titanium dioxide sol-gel.

In an embodiment of the present invention, the sol-gel reaction may further include to perform a condensation reaction, so as to form a precursor from the titanium alkoxide and the acid. Subsequently, the precursor is subjected to perform a high-temperature and high-pressure reaction, so as to form the titanium dioxide sol-gel, followed by adding the carbon black nanoparticles into the titanium dioxide sol-gel for forming the carbon black-mixed titanium dioxide sol-gel.

According to the aforementioned aspect of the present invention, a DSSC is provided. The DSSC may include an anode electrode, a cathode electrode, and an electrolyte layer disposed between the anode and the cathode electrodes. The anode electrode may include a transparent substrate, a carbon black-mixed titanium dioxide layer and a dye layer. The carbon black-mixed titanium dioxide layer may be disposed on the transparent substrate, and the dye layer may be disposed on the titanium dioxide layer. The titanium dioxide nanoparticles may have an anatase phase, and they may have a specific surface area of, for example, to 90 m²/g to 250 m²/g. The carbon black nanoparticles may have an average diameter of, for example, 20 nm to 100 nm, and a weight ratio of the carbon black nanoparticles to the titanium dioxide nanoparticles may be, for example, 1:10 to 1:10000.

In an embodiment of the present invention, the cathode electrode may be made of a material of platinum, gold, carbon or an electrically conductive polymer.

In an embodiment of the present invention, the electrolyte layer is a liquid-, gel- or solid-state, and the electrolyte layer may include an acetonitrile solution containing iodine, lithium iodide and 4-isobutyl pyridine.

With application to the aforementioned DSSC, the anode electrode thereof, and the method of manufacturing the same of the present invention, they include the anode electrode having a titanium dioxide layer mixed with a desired ratio of carbon black nanoparticles to increase the conductivity of the anode. Thereby, the conversion efficiency of the solar energy to electricity for the DSSC is effectively improved.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 depicts a process flow diagram of the carbon black-mixed titanium dioxide sol-gel according to a preferred embodiment of the present invention.

### DETAILED DESCRIPTION OF THE PREFERRED EMBODIMENT

Accordingly, the present invention provides a DSSC, an anode electrode thereof, and a method of manufacturing the same, which include the anode electrode having titanium dioxide layer mixed with a desired ratio of carbon black nanoparticles. The less and environmentally friendly dye can increase conductivity of the anode, thereby effectively improving the conversion efficiency of the solar energy to electricity for the DSSC.

Structure of Anode Electrode

In detail, the anode electrode may include a transparent substrate, a carbon black-mixed titanium dioxide layer and a dye layer. The carbon black-mixed titanium dioxide layer may be disposed on the transparent substrate, and the dye layer may be disposed on the titanium dioxide layer. In an embodiment, the transparent substrate may be made of glass or plastic, and the dye may include but not be limited in, for example, a ruthenium complex dye or mercurochrome dye.

Examples of the ruthenium complex dye may include but not be limited in N3 dye (cis-bis(isothiocyanato)bis(2,2′-bipyridyl-4,4′-dicarboxylato)-ruthenium (II); Ruthenium 535), N712 dye ((Bu₄N)₄[Ru(dcbpy)₂(NCS)₂] Complex), N719 dye (cis-bis(isothiocyanato)bis(2,2′-bipyridyl-4,4′-dicarboxylato)-ruthenium (II) bis-tetrabutylammonium; Ruthenium 535 bis-TBA), N749 dye (tris (isothiocyanato)-ruthenium (II)-2,2′:6′,2″-terpyridine-4,4′,4″-tricarboxylic acid, tris-tetrabutylammonium salt; Ruthenium 620-1H3TBA; 620 dye; black dye), 470 dye (tris(2,2′bipyridyl-4,4′ dicarboxylato) ruthenium (II) dichloride; Ruthenium 470), 505 dye (cis-bis(cyanido) (2,2′bipyridyl-4,4′ dicarboxylato) ruthenium (II); Ruthenium 505), or Z907 dye (cis-bis(isothiocyanato)(2,2′-bipyridyl-4,4′-dicarboxylato)(2,2′-bipyridyl-4,4′-di-nonyl) ruthenium (II); Ruthenium 520-DN). In another embodiment of the present invention, the dye layer is N719 dye layer.

The present invention utilizes less and environmentally friendly dye to increase conductivity of the anode, and in an embodiment, a desired ratio of carbon black nanoparticles may be mixed into the titanium dioxide layer so as to facilitate to achieve the above purpose. More specifically, the carbon black-mixed titanium dioxide layer can include titanium dioxide nanoparticles and carbon black nanoparticles.

In an embodiment, the titanium dioxide nanoparticles may have an anatase phase, and they may have a specific surface area of, for example, to 90 m²/g to 250 m²/g. In another embodiment, the carbon black nanoparticles may have an average diameter of, for example, 20 nanometers (nm) to 100 nm. In an embodiment, a weight ratio of the carbon black nanoparticles to the titanium dioxide nanoparticles may be, for example, 1:10 to 1:10000.

The carbon black-mixed titanium dioxide layer can be manufactured by several processes and exemplified as follows.

Method of Manufacturing Carbon Black-Mixed Titanium Dioxide Layer

The carbon black-mixed titanium dioxide layer can be manufactured by a sol-gel reaction or other methods. In the sol-gel reaction, the carbon nanoparticles may be added into the titanium dioxide sol-gel during various processing stages for obtaining the carbon black-mixed titanium dioxide sol-gel.

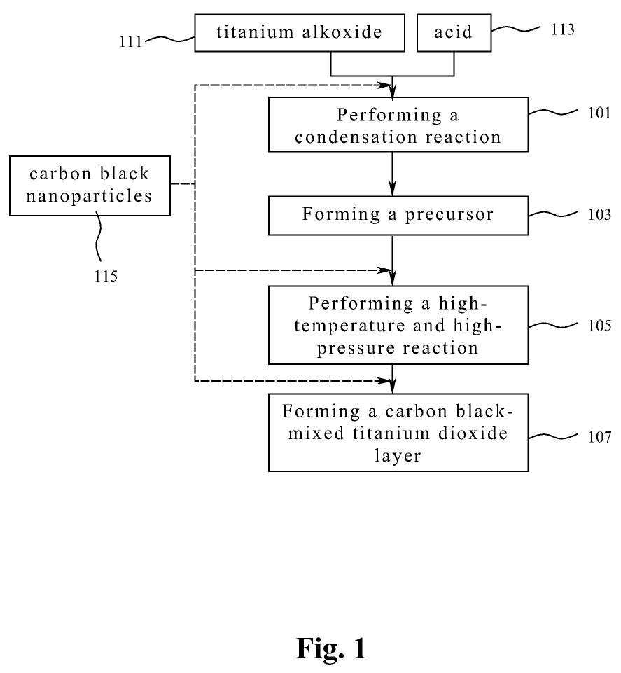

Reference is made to FIG. 1, which depicts a process flow diagram of the carbon black-mixed titanium dioxide sol-gel according to a preferred embodiment of the present invention. In an embodiment, in step 101, the sol-gel reaction may further include to perform a condensation reaction under a temperature of 70° C. to 90° C., for example, so as to form a precursor shown in step 103 by mixing with the carbon black nanoparticles from the titanium alkoxide 111, the carbon black nanoparticles 115 and the acid 113. Subsequently, the precursor mixed with the carbon black nanoparticles is subjected to perform a high-temperature and high-pressure reaction (i.e. a hydrothermal reaction) shown in step 105, so as to form the carbon black-mixed titanium dioxide sol-gel shown in step 107. The titanium alkoxide may be, for example, titanium isopropoxide, and the acid may be, for example, nitric acid, hydrochloric acid or acetic acid. The titanium dioxide sol-gel may include anatase-phase titanium dioxide nanoparticles, in which the specific surface area of the titanium dioxide nanoparticles, the average diameter of the carbon black nanoparticles, the weight ratio of the carbon black nanoparticles to the titanium dioxide nanoparticles are described as above rather than addressing the related details herein. The closed system may be an autoclave, for example.

Alternatively, in another embodiment, the sol-gel reaction may further include to perform a condensation reaction shown in step 101, so as to form a precursor from the titanium alkoxide 111 and the acid 113 shown in step 103. Subsequently, the precursor is added with the carbon black nanoparticles 115 and subjected to perform a high-temperature and high-pressure reaction shown in step 105, so as to form the carbon black-mixed titanium dioxide sol-gel shown in step 107 of FIG. 1.

Alternatively, in further embodiment, the sol-gel reaction may further include to perform a condensation reaction in step 101, so as to form a precursor from the titanium alkoxide 111 and the acid 113 shown in step 103. Subsequently, the precursor is subjected to perform a high-temperature and high-pressure reaction shown in step 105, so as to form the titanium dioxide sol-gel, followed by adding the carbon black nanoparticles 115 into the titanium dioxide sol-gel for forming the carbon black-mixed titanium dioxide sol-gel in step 107 of FIG. 1.

In addition to the carbon black nanoparticles added into the various stages of the titanium dioxide sol-gel, in a still another embodiment, the carbon black nanoparticles and commercial titanium dioxide powder in a weight ratio of 1:10 to 1:10000, for example, are mixed and stirred well in the ethanol solution, so as to obtain the carbon black-mixed titanium dioxide dispersion for subsequently coating on the transparent substrate.

Method of Manufacturing Anode Electrode of DSSC

In an embodiment, the anode electrode is produced as follow. First of all, a titanium alkoxide, carbon black nanoparticles and an acid may be mixed to perform a sol-gel reaction, so as to form a carbon black-mixed titanium dioxide sol-gel, in which the titanium alkoxide, the carbon black nanoparticles, the acid and the sol-gel reaction are described as above rather than addressing the related details herein.

Next, the carbon black-mixed titanium dioxide sol-gel may be coated on a transparent substrate, so as to form a carbon black-mixed titanium dioxide layer. The coating method, such as spin-coating, blade-coating or the like, are well understood and freely chosen by one person skilled in the art, and thus the related details are unnecessary to be addressed herein Later, a dye layer may be formed on the carbon black-mixed titanium dioxide layer. The suitable dye layer may include but be not limited in, for example, a ruthenium complex dye or mercurochrome dye. In an embodiment, a soaking step is performed to soak the transparent substrate with the carbon black-mixed titanium dioxide layer in a dye solution, so as to form the dye layer. The examples of the ruthenium complex dye are exemplified as above rather than addressing the related details herein.

The resulted anode electrode can be further assembled with a cathode electrode and an electrolyte layer, so as to form a DSSC. Thereinafter, the assembly of the DSSC is exemplified as follows.

Assembly of DSSC

The resulted anode electrode can be further assembled with a cathode electrode and an electrolyte layer, so as to form a DSSC. In an embodiment, the cathode electrode may be made of a material including but not being limited in platinum, gold, carbon or an electrically conductive polymer, in which the electrically conductive polymer may be, for example, polypyrrole, polyaniline or polythiophene. In an embodiment, the electrolyte layer is a liquid-, gel- or solid-state, and the electrolyte layer may include an acetonitrile solution containing iodine, lithium iodide and 4-isobutyl pyridine.

It is worth mentioning that the anode of the DSSC of the present invention has the titanium dioxide layer mixed with a desired ratio of carbon black nanoparticles to increase the conductivity of the anode. Thereby, the conversion efficiency of the solar energy to electricity for the DSSC is effectively improved better that the prior DSSC and costs less.

Thereinafter, various applications of the present invention will be described in more details referring to several exemplary embodiments below, while not intended to be limiting. Thus, one skilled in the art can easily ascertain the essential characteristics of the present invention and, without departing from the spirit and scope thereof, can make various changes and modifications of the invention to adapt it to various usages and conditions.

### Example 1

### Preparation of Titanium Dioxide Sol-Gel

EXAMPLE 1 is related to prepare titanium dioxide sol-gel. Firstly, 12.5 mL of titanium isopropoxide is slowly added into 0.1 M nitric acid solution, 5.0 M hydrochloric acid solution or 8.0 M acetic acid solution until the white precipitation is fully salted-out. At this time, it keeps continuously stirring the solution until the white precipitation is fully resolved and the solution is clear. Next, the nitric acid solution, hydrochloric acid solution or acetic acid solution of the titanium isopropoxide is put into an autoclave (effective volume: about 150 mL, Tsao-Yi Co., Taiwan), continuously stirred under about 80° C. for about 8 hours until the solution becomes white turbid precursor, the precursor is heated to about 200° C. and kept stirring for 2 to 10 hours. Alternatively, the nitric acid solution, hydrochloric acid solution or acetic acid solution of the titanium isopropoxide is put into an autoclave and heated to about 200° C. and kept stirring for 2 hours. Later, the resulted sol-gel is washed to be neutral and the titanium dioxide sol-gel is obtained.

Reference is made to Table 1, which is an analyzing result of the processing conditions and characteristics of the titanium dioxide sol-gel according to an embodiment of the present invention. According to the result of Table 1, the titanium dioxide nanoparticles, which is obtained by calcinating the titanium dioxide sol-gel synthesized by 8.0 M acetic acid solution under about 150° C., has better crystal phase (100% anatase-phase crystal), crystal size (i.e. crystallized domain size) and full width at half maximum (FWHM) according to the diffraction angle than the ones obtained by calcinating the titanium dioxide sol-gel synthesized by 0.1 M nitric acid solution or 5.0 M hydrochloric acid solution.

TABLE 1

| | Titanium dioxide sol-gel | | |
|---|---|---|---|
| | Acids | | |
| | 0.1 M nitric | 5.0 M | 8 M acetic |
| | acid | hydrochloric | acid |
| | solution | acid solution | solution |
| Calcinating temperature | 150° C. | 150° C. | 150° C. |
| Anatase-phase crystal | 86% | 87% | 100% |
| Rutile-phase crystal | 14% | 0% | 0% |
| Crystallized domain size (nm) | 7.9 | 7.7 | 6.6 |
| Full width at half maximum | 1.03 | 1.06 | 1.24 |
| (FWHM) | | | |

Reference is made to Table 2, which is another analyzing result of the processing conditions and characteristics of the titanium dioxide sol-gel according to another embodiment of the present invention. According to the result of Table 2, the titanium dioxide sol-gel can be obtained under the high-temperature and high-pressure reaction for 1 to 10 hours. The titanium dioxide sol-gel is calcinated under about 150° C. to obtain the titanium dioxide nanoparticles having a specific surface area of 90 m²/g to 250 m²/g and the particle size of 10 nm to 40 nm. The specific surface area is measured according to the Brunauer Emmett Teller (BET) method. However, the titanium dioxide nanoparticles, which is obtained by calcinating the titanium dioxide sol-gel for about 2 hours, has significantly better specific surface area and particle size than the ones obtained by calcinating the titanium dioxide sol-gel for 3 to 10 hours. That is to say, by calcinating the titanium dioxide sol-gel for about 2 hours can obtain the titanium dioxide nanoparticles with larger specific surface area and smaller particle size.

TABLE 2

Titanium dioxide sol-gel
Reaction period (hr)
of high-temperature
and high-pressure
reaction

| | 2 | 3 | 6 | 10 |
|---|---|---|---|---|
| BET (m²/g) | 226.9 | 150.7 | 128.9 | 94.4 |
| Particle size (nm) | 10 | 17 | N.D. | 34 |

(Note: “N.D”. is referred to be unmeasured.)

### Example 2

### Preparation of Carbon Black-Mixed Titanium Dioxide Sol-Gel

EXAMPLE 2 is related to prepare a carbon black-mixed titanium dioxide sol-gel obtained by methods A, B or C, which is added with carbon black nanoparticles during various stages.

Method A: Firstly, 12.5 mL of titanium isopropoxide is slowly added into 8.0 M acetic acid solution until the white precipitation is fully salted-out. At this time, it keeps continuously stirring the solution until the white precipitation is fully resolved and the solution is clear. Next, the carbon black nanoparticles are added into the acetic acid solution of the titanium isopropoxide and continuously stirred for a half hour. Later, the acetic acid solution of the titanium isopropoxide mixed with the carbon black nanoparticles is put into the autoclave the same with EXAMPLE 1, continuously stirred under about 80° C. for about 8 hours until the solution becomes white turbid precursor mixed with the carbon black nanoparticles, the precursor is heated to about 200° C. and kept stirring for 2 to 10 hours. Alternatively, the precursor mixed with the carbon black nanoparticles is heated to about 200° C. and kept stirring for 2 hours. Subsequently, the resulted sol-gel is washed to be neutral and the titanium dioxide sol-gel is obtained.

Method B: Firstly, 12.5 mL of titanium isopropoxide is slowly added into 8.0 M acetic acid solution until the white precipitation is fully salted-out. At this time, it keeps continuously stirring the solution until the white precipitation is fully resolved and the solution is clear. Next, the acetic acid solution of the titanium isopropoxide is put into the autoclave the same with EXAMPLE 1, continuously stirred under about 80° C. for about 8 hours until the solution becomes white turbid precursor, the carbon black nanoparticles are added into the precursor and kept stirring for a half hour. The precursor mixed with the carbon black nanoparticles is heated to about 200° C. and kept stirring for 2 to 10 hours. Alternatively, the precursor mixed with the carbon black nanoparticles is heated to about 200° C. and kept stirring for 2 hours. Subsequently, the resulted sol-gel is washed to be neutral and the titanium dioxide sol-gel is obtained.

Method C: The carbon black nanoparticles and commercial titanium dioxide powder (Aeroxide®, Evonik Industries AG, Germany; old product name: Degussa P-25; purity: >99.5%) are mixed and stirred well into the ethanol solution, so as to obtain a titanium dioxide dispersion mixed with the carbon black nanoparticles.

### Example 3

### Preparation of Carbon Black-Mixed Titanium Dioxide Membrane Electrode

EXAMPLE 3 is related to prepare a carbon black-mixed titanium dioxide membrane electrode. At first, in this example, the carbon black-mixed titanium dioxide sol-gel is dispersed in 95 wt. % ethanol solution for obtaining a slurry with a solid content of 15 wt. %.

Next, the slurry is blade-coated on a transparent glass or plastic substrate having indium tin oxide (ITO) (the plastic substrate may be made of poly(ethylene terephthalate) (PET), for example), and then the coated transparent substrate is placed and dried for about 30 minutes. Afterward, the coated transparent substrate is dried on a hot plate under about 50° C. for 10 minutes, so as to obtain the carbon black-mixed titanium dioxide membrane electrode.

Reference is made to Table 3, which is an analyzing result of BET, crystallized domain size, average particle size and crystallinity of the carbon black-mixed titanium dioxide membrane electrode according to another embodiment of the present invention, in which the crystallized domain size of the anatase-phase of the titanium dioxide is detected by X-ray diffraction (XRD) instrument, and the average particle size is measured by transmission electron microscope (TEM). According to the result of Table 3, when the weight ratio of the carbon black nanoparticles to the titanium dioxide nanoparticles is 1:10 to 1:10000, the BET is 100 m²/g to 250 m²/g, the crystallized domain size is 10 nm to 15 nm, the average particle size is 7 nm to 20 nm, and the crystallinity is 60% to 100%.

TABLE 3

| | Weight ratio | | | Average | Crystallinity |
|---|---|---|---|---|---|
| | (carbon | BET | Crystallized | particle | (crystallized |
| | black/TiO₂) | (m²/g) | domain size | size | domain |
| TiO₂ only | 0% | 226 | 6.6 nm | 7.5 nm | 88% |
| Method A | 1% | 163 | 11.9 nm | 12.4 nm | 96% |
| | 3% | 105 | 20.0 nm | 22.5 nm | 88% |
| | 5% | 132 | 12.3 nm | 14.4 nm | 85% |
| | 10% | 107 | 11.1 nm | 16.1 nm | 69% |
| | 20% | 159 | 16.0 nm | 15.8 nm | >100% |
| Method B | 1% | 102 | 13.1 nm | 19.3 nm | 68% |
| | 3% | 107 | 11.6 nm | 19.9 nm | 58% |
| | 5% | 127 | 10.2 nm | 13.1 nm | 78% |
| | 10% | 121 | 11.3 nm | 12.8 nm | 88% |
| | 20% | 136 | 10.4 nm | 18.0 nm | 58% |
| Carbon | — | 102 | N.D. | >30 nm | N.D. |
| black | | | | | |

(Note: “N.D”. is referred to be unmeasured.)

Reference is made to Table 4, which is a size distribution result of the carbon black and titanium dioxide nanoparticles of the carbon black-mixed titanium dioxide membrane electrode according to an embodiment of the present invention. According to the result of Table 4, when the weight ratio of the carbon black nanoparticles to the titanium dioxide nanoparticles is 1:10 to 1:10000, the average

TABLE 4

| | Weight ratio | Below | | | | | Above | Average |
|---|---|---|---|---|---|---|---|---|
| | (carbon | 10 nm | 10 nm~15 nm | 15 nm~20 nm | 20 nm~25 nm | 25 nm~30 nm | 30 nm | particle |
| Method | 1% | 19.70% | 73.50% | 6% | 0.80% | 0% | 0% | 12.40 |
| | 3% | 1.1% | 17.6% | 18.7% | 15.4% | 47.2% | 1.1% | 22.5 |
| | 5% | 16.40% | 40.70% | 40% | 2.90% | 0% | 0% | 14.42 |
| | 10% | 7.10% | 31.90% | 52.90% | 8% | 0% | 0% | 16.90 |
| | 20% | 9.5% | 42.1% | 3.2% | 14.3% | 30.9% | 9.5% | 15.8 |
| Method B | 1% | 0% | 20.20% | 34.20% | 44.30% | 1.30% | 0% | 19.33 |
| | 3% | 2.30% | 9.40% | 43.80% | 36.70% | 7.80% | 0% | 19.91 |
| | 5% | 24.80% | 54% | 16.80% | 4.40% | 0% | 0% | 13.04 |
| | 10% | 21.60% | 62.40% | 14.40% | 0.80% | 0.80% | 0% | 12.84 |
| | 20% | 2.50% | 14.10% | 59% | 23% | 0% | 0% | 17.96 |
| Carbon | — | 0% | 0% | 1.3% | 2.6% | 2.6% | 93.5% | >30 nm |
| black | | | | | | | | |
| only | | | | | | | | |

### Example 4

### Preparation of Carbon Black-Mixed Titanium Dioxide Anode Electrode

EXAMPLE 4 is related to prepare a carbon black-mixed titanium dioxide anode electrode. At first, in this example, the membrane electrode produced by EXAMPLE 3 is soaked into the ethanol solution (Fisher Scientific; purity: 99.9 wt %) of 5×10⁻⁴ M N719 dye for about 12 hours, so as to form N719 dye layer on the carbon black-mixed titanium dioxide layer. Next, the N719 dye absorbing membrane electrode is taken out, roughly rinsed by ethanol and dried, so as to obtain the anode electrode of the DSSC, in which the anode electrode includes the carbon black-mixed titanium dioxide layer and the N719 dye layer disposed thereon.

### Example 5

### Preparation of DSSC

EXAMPLE 5 is related to prepare a DSSC. At first, in this example, the anode electrode of EXAMPLE 4 serves as an anode, and a cathode electrode is disposed separately opposing to the anode, in which the cathode electrode includes another conductive substrate coated with platinum. An electrolyte is filled between the anode and the cathode electrode, so as to obtain the DSSC with a general sandwich structure. The electrolyte comprises an acetonitrile (ALDRICH; purity: 99.5%) solution containing 0.05 M iodine (MERCK; purity: 99.8%), 0.5 M lithium iodide (MERCK; purity: >99.8%) and 0.05M 4-isobutyl pyridine.

### Example 6

### Evaluation of Optoelectrical Characteristics of DSSC

EXAMPLE 6 is related to evaluate optoelectrical characteristics of DSSC of EXAMPLE 5, for example, short circuit current (Isc), open circuit voltage (Voc), fill factor (FF) and solar energy to electricity conversion efficiency (η). In this example, a 450 W xenon (Xe) short arc lamp (Lot-Oriel Ltd.) serves as a light source of the system for evaluating the DSSC performance, a filter serves to modify the spectral output of the Xe short arc lamp to match solar conditions for providing a simulated solar radiation, and a photodetector (Optical Power meter, Solar Light Company, Inc. PMA-2141) serves to adjust the simulated solar radiation to 100 W/cm² of light intensity. After the light source is stable, the DSSC of EXAMPLE 5 is irradiated under the beam from the adjusted light source and electrically connected to positive and negative terminals of a power supply that provides a positive voltage controlled by a sourcemeter. The output current of the DSSC is measured to obtain a current-voltage (I-V) curve and optoelectrical characteristics, for example, short circuit current (Isc), open circuit voltage (Voc), fill factor (FF) and solar energy to electricity conversion efficiency (η). The results of the optoelectrical characteristics are listed as below as Tables 5 and 6.

The “short circuit current (Isc)” herein is referred to a working current of a solar cell under the short circuit condition, and also referred to a “short circuit light current”, which is equal to an absolute quantity of photons converting to electron-hole pairs, while the output voltage of the solar cell is zero. Typically, the higher short circuit current of the solar cell is better.

The “open circuit voltage (Voc)” herein is referred to a working current of a solar cell under the open circuit condition, while the output current of the solar cell is zero. Typically, the higher open circuit voltage of the solar cell is better.

The “fill factor (FF)” herein is referred to a ratio of a maximum output power (Pₘₐₓ=(I×V)ₘₐₓ) of a solar cell circuit, with respect to a maximum output power (the multiplied product of Voc and Isc) of a solar cell, while the output current of the solar cell is zero. Typically, the higher open circuit voltage of the solar cell is better:

$$FF = \frac{{P}_{max}}{{I}_{sc} \times {V}_{oc}} = \frac{{( I \times V )}_{max}}{{I}_{sc} \times {V}_{oc}} \qquad ( I )$$

The “solar energy to electricity conversion efficiency (η)” herein is referred to a percentage of a maximum output power (Pₘₐₓ) of a light receiving unit area of a solar cell with respect to an energy density of the emitted sunlight (P_{light}), and it is obtained by the following formula (II). Typically, the expected value of the solar energy to electricity conversion efficiency of a solar cell is 1, but the actual one is less than 1. The higher solar energy to electricity conversion efficiency is better:

$$η ( \% ) = \frac{{( I \times V )}_{max}}{{P}_{light}} \times 100 \% \qquad ( II )$$

Reference is made to Table 5, which is the optoelectrically performance data of the DSSC according to an embodiment of the present invention, in which using the method of EXAMPLE 1 without mixing with the carbon black nanoparticles produces the titanium dioxide layer of the anode electrode of the DSSC. According to the result of Table 5, the DSSC that has the anode electrode with the titanium dioxide layer of EXAMPLE 1 either on the glass or plastic substrate has the solar energy to electricity conversion efficiency (η) of about 3% to 5% that is equal to the one of the commercial DSSC.

TABLE 5

Transparent substrate

| | ITO-Glass substrate | ITO-PET substrate |
|---|---|---|
| Voc (V) | 0.65 | 0.73 |
| Isc (mA/cm²) | 1.44 | 0.91 |
| FF | 0.50 | 0.44 |
| η (%) | 4.61 | 3.01 |

(Note: The light intensity is 10 mW/cm²)

Reference is made to Table 6, which is the optoelectrically performance data of the DSSC according to another embodiment of the present invention, in which using Methods A and C of the method of EXAMPLE 2 produces the carbon black-mixed titanium dioxide layer of the anode electrode of the DSSC mixed with various ratios of the carbon black nanoparticles. In Table 6, Methods A-1 to A-8 are referred to the anode produced by using Method A of EXAMPLE 2 and the carbon black and titanium dioxide nanoparticles in a weight ratio of 0.01%, 0.1%, 0.5%, 1%, 3%, 5%, 10% and 20%. Methods C-1 to C-8 are referred to the anode produced by using Method C of EXAMPLE 2 and the carbon black and titanium dioxide nanoparticles in a weight ratio of 0.01%, 0.1%, 0.5%, 1%, 3%, 5%, 10% and 20%.

TABLE 6

| Method of | | | | | |
|---|---|---|---|---|---|
| producing | | | | | |
| the carbon | Weight | | | | |
| black-mixed | ratio | | | | |
| titanium | (carbon | Isc | Voc | | |
| dioxide layer | black/TiO₂) | (mA/cm²) | (mV) | FF | η (%) |
| Titanium dioxide only | | 8.75 | 730 | 0.37 | 2.36 |
| A-1 | 0.01% | 11.63 | 836 | 0.38 | 3.69 |
| A-2 | 0.1% | 3.88 | 642 | 0.32 | 0.80 |
| A-3 | 0.5% | 5.55 | 537 | 0.38 | 1.13 |
| A-4 | 1% | 4.24 | 372 | 0.29 | 0.46 |
| A-5 | 3% | 2.40 | 239 | 0.26 | 0.15 |
| A-6 | 5% | 1.36 | 119 | 0.31 | 0.05 |
| A-7 | 10% | 2.20 | 194 | 0.28 | 0.12 |
| A-8 | 20% | N.D. | N.D. | N.D. | N.D. |
| C-1 | 0.01% | 12.27 | 866 | 0.40 | 4.25 |
| C-2 | 0.1% | 9.39 | 731 | 0.36 | 2.47 |
| C-3 | 0.5% | 4.08 | 403 | 0.27 | 0.44 |
| C-4 | 1% | 0.08 | 254 | 0.24 | 0.00 |
| C-5 | 3% | 0.16 | 60 | 0.37 | 0.00 |
| C-6 | 5% | 0.16 | 119 | 0.34 | 0.01 |
| C-7 | 10% | N.D. | N.D. | N.D. | N.D. |
| C-8 | 20% | N.D. | N.D. | N.D. | N.D. |

(Note: The light intensity is 100 mW/cm², and “N.D”. is referred to be unmeasured.)

According to the result of Table 6, less carbon black nanoparticles mixed into the titanium dioxide layer beneficially improve the short circuit current (Isc) and open circuit voltage (Voc) but without affecting the fill factor (FF). More specifically, except for the DSSC produced by Method A-2 with lower Isc and Voc, the DSSCs produced by Method A-1, C-1 and C-2 have Isc of about 9.39 mA/cm² to 12.27 mA/cm² and Voc of about 733 mV to 866 mV, both of which are higher than Isc (8.75 mA/cm²) and Voc (730 mV) of the DSSC produced without mixing with carbon black nanoparticles (i.e. titanium dioxide only). Moreover, except for the DSSC produced by Method A-2 with lower FF (0.32), the DSSCs produced by Method A-1, C-1 and C-2 have FF of about 0.36 to 0.40, which is approximately equal or a little higher than FF (0.37) of the DSSC produced without mixing with carbon black nanoparticles (i.e. titanium dioxide only)

Reference is made to Table 6 again. Less carbon black nanoparticles mixed into the titanium dioxide layer beneficially improve the solar energy to electricity conversion efficiency (η) of the DSSC. In detail, the DSSCs produced by Methods A-1 to A-7 or C-1 to C-7 have η of 0% to 1%. Moreover, when the DSSCs produced by mixing less carbon black nanoparticles into the titanium dioxide layer, for example, the DSSCs produced by Methods A-1 to A-4 or C-1 to C-4 have η of 0.1% to 1%. Furthermore, when the DSSCs produced by mixing more little carbon black nanoparticles into the titanium dioxide layer, for example, the DSSC produced by Methods A-1, C-1 or C-2 has η of 0.55% to 0.93%. In other words, less carbon black nanoparticles mixed into the titanium dioxide layer significantly improve the solar energy to electricity conversion efficiency of the DSSC.

Therefore, less carbon black nanoparticles mixed into the titanium dioxide layer indeed improve the short circuit current, open circuit voltage and solar energy to electricity conversion efficiency of the DSSC but without affecting the fill factor.

By the way, it is necessarily supplemented that, the specific titanium alkoxide, specific acids, specific carbon black nanoparticles, the specific transparent substrate, specific cathode electrode, specific electrolyte and the like are employed as exemplary embodiments in the present invention for evaluating the DSSC and the anode electrode of the present invention, however, as is understood by a person skilled in the art, the different titanium alkoxide, specific acids, specific carbon black nanoparticles, different transparent substrate, different cathode electrode and different electrolyte can be employed in the present invention and be any combined thereof rather than limiting to the aforementioned examples.

According to the preferred embodiments of the present invention, the aforementioned DSSC, the anode electrode thereof, and the method of manufacturing the same of the present invention, which advantageously include the anode electrode having a titanium dioxide layer mixed with a desired ratio of carbon black nanoparticles to increase the conductivity of the anode. The less and environmentally friendly dye can increase conductivity of the anode, thereby effectively improving the conversion efficiency of the solar energy to electricity for the DSSC.

As is understood by a person skilled in the art, the foregoing preferred embodiments of the present invention are illustrated of the present invention rather than limiting of the present invention. It is intended to cover various modifications and similar arrangements included within the spirit and scope of the appended claims. Therefore, the scope of which should be accorded to the broadest interpretation so as to encompass all such modifications and similar structure.

1. An anode electrode of a dye-sensitized solar cell (DSSC), comprising:
a transparent substrate;
a carbon black-mixed titanium dioxide layer disposed on the transparent substrate, wherein the carbon black-mixed titanium dioxide layer comprises:
titanium dioxide nanoparticles, wherein the titanium dioxide nanoparticles have an anatase phase and a specific surface area of to 90 m²/g to 250 m²/g ; and
carbon black nanoparticles, wherein the carbon black nanoparticles have an average diameter of 20 nanometers (nm) to 100 nm, and a weight ratio of the carbon black nanoparticles to the titanium dioxide nanoparticles is 1:10 to 1:10000; and
a dye layer disposed on the carbon black-mixed titanium dioxide layer.

2. The anode electrode of the DSSC according to claim 1, wherein the dye is selected from the group consisted of ruthenium complex dye and mercurochrome dye.

3. The anode electrode of the DSSC according to claim 1, wherein the ruthenium complex dye is selected from the group consisted of N3 dye (cis-bis(isothiocyanato)bis(2,2′-bipyridyl-4,4′-dicarboxylato)-ruthenium (II); Ruthenium 535), N712 dye ((Bu₄N)₄[Ru(dcbpy)₂(NCS)₂] Complex), N719 dye (cis-bis(isothiocyanato)bis(2,2′-bipyridyl-4,4′-dicarboxylato)-ruthenium (II) bis-tetrabutylammonium; Ruthenium 535 bis-TBA), N749 dye (tris (isothiocyanato)-ruthenium (II)-2,2′:6′,2″-terpyridine-4,4′,4″-tricarboxylic acid, tris-tetrabutylammonium salt; Ruthenium 620-1H3TBA; 620 dye; black dye), 470 dye (tris(2,2′bipyridyl-4,4′ dicarboxylato) ruthenium (II) dichloride; Ruthenium 470), 505 dye (cis-bis(cyanido) (2,2′bipyridyl-4,4′ dicarboxylato) ruthenium (II); Ruthenium 505), and Z907 dye (cis-bis(isothiocyanato) (2,2′-bipyridyl-4,4′-dicarboxylato)(2,2′-bipyridyl-4,4′-di-nonyl) ruthenium (II); Ruthenium 520-DN).

4. The anode electrode of the DSSC according to claim 1, wherein the weight ratio of the carbon black nanoparticles to the titanium dioxide nanoparticles is 1:100 to 1:10000.

5. The anode electrode of the DSSC according to claim 1, wherein the transparent substrate is made of glass or plastic.

6. A method of manufacturing an anode electrode of a DSSC, comprising:
mixing a titanium alkoxide, carbon black nanoparticles and an acid to perform a sol-gel reaction, so as to form a carbon black-mixed titanium dioxide sol-gel, wherein the titanium dioxide sol-gel comprises anatase-phase titanium dioxide nanoparticles with a specific surface area of to 90 m²/g to 250 m²/g, the carbon black nanoparticles have an average diameter of 20 nm to 100 nm, and a weight ratio of the carbon black nanoparticles to the titanium dioxide nanoparticles is 1:10 to 1:10000;
coating the carbon black-mixed titanium dioxide sol-gel on a transparent substrate, so as to form a carbon black-mixed titanium dioxide layer; and
form a dye layer on the carbon black-mixed titanium dioxide layer.

7. The method of manufacturing the anode electrode of the DSSC according to claim 6, wherein the titanium alkoxide is titanium isopropoxide.

8. The method of manufacturing the anode electrode of the DSSC according to claim 6, wherein the acid is nitric acid, hydrochloric acid or acetic acid.

9. The method of manufacturing the anode electrode of the DSSC according to claim 11, wherein the dye layer has a material selected from the group consisted of ruthenium complex dye and mercurochrome dye.

10. The method of manufacturing the anode electrode of the DSSC according to claim 9, wherein the ruthenium complex dye is selected from the group consisted of N3 dye, N712 dye, N719 dye, N749 dye, 470 dye, 505 dye, and Z907 dye.

11. The method of manufacturing the anode electrode of the DSSC according to claim 6, wherein the weight ratio of the carbon black nanoparticles to the titanium dioxide nanoparticles is 1:100 to 1:10000.

12. The method of manufacturing the anode electrode of the DSSC according to claim 6, wherein the sol-gel reaction further comprises:
performing a condensation reaction, so as to make the titanium alkoxide, the carbon black nanoparticles and the acid for forming a precursor mixed with the carbon black nanoparticles; and
subjecting the precursor mixed with the carbon black nanoparticles to perform a high-temperature and high-pressure reaction, so as to form the carbon black-mixed titanium dioxide sol-gel.

13. The method of manufacturing the anode electrode of the DSSC according to claim 6, wherein the sol-gel reaction further comprises:
performing a condensation reaction, so as to make the titanium alkoxide and the acid for forming a precursor; and
adding the carbon black nanoparticles into the precursor and subjecting the precursor and the carbon black nanoparticles to perform a high-temperature and high-pressure reaction, so as to form the carbon black-mixed titanium dioxide sol-gel.

14. The method of manufacturing the anode electrode of the DSSC according to claim 6, wherein the sol-gel reaction further comprises:
performing a condensation reaction, so as to make the titanium alkoxide and the acid for forming a precursor;
subjecting the precursor to perform a high-temperature and high-pressure reaction, so as to form a titanium dioxide sol-gel; and
adding the carbon black nanoparticles into the titanium dioxide sol-gel, so as to form the carbon black-mixed titanium dioxide sol-gel.

15. The method of manufacturing the anode electrode of the DSSC according to claim 12, wherein the high-temperature and high-pressure reaction is performed under a temperature of 180° C. to 240° C. in a closed system.

16. The method of manufacturing the anode electrode of the DSSC according to claim 15, wherein the closed system is an autoclave.

17. The method of manufacturing the anode electrode of the DSSC according to claim 6, wherein the step of forming the dye layer is to perform a soaking step, so as to soaking the transparent substrate with the carbon black-mixed titanium dioxide layer in a dye solution.

18. The method of manufacturing the anode electrode of the DSSC according to claim 6, wherein the transparent substrate is made of glass or plastic.

19. A DSSC, comprising:
an anode electrode comprising:
a transparent substrate;
a carbon black-mixed titanium dioxide layer disposed on the transparent substrate, wherein the carbon black-mixed titanium dioxide layer comprises:
titanium dioxide nanoparticles, wherein the titanium dioxide nanoparticles have an anatase phase and a specific surface area of to 90 m²/g to 250 m²/g ; and
carbon black nanoparticles, wherein the carbon black nanoparticles have an average diameter of 20 nm to 100 nm, and a weight ratio of the carbon black nanoparticles to the titanium dioxide nanoparticles is 1:10 to 1:10000;
a dye layer disposed on the carbon black-mixed titanium dioxide layer;
a cathode electrode; and
an electrolyte layer disposed between the anode and the cathode electrodes.

20. The DSSC according to claim 19, wherein the dye layer has a material selected from the group consisted of ruthenium complex dye and mercurochrome dye.

21. The DSSC according to claim 20, wherein the ruthenium complex dye is selected from the group consisted of N3 dye, N712 dye, N719 dye, N749 dye, 470 dye, 505 dye, and Z907 dye.

22. The DSSC according to claim 19, wherein the weight ratio of the carbon black nanoparticles to the titanium dioxide nanoparticles is 1:100 to 1:10000.

23. The DSSC according to claim 19, wherein the transparent substrate is made of glass or plastic.

24. The DSSC according to claim 19, wherein the cathode electrode is made of a material of platinum, gold, carbon or an electrically conductive polymer.

25. The DSSC according to claim 24, wherein the electrically conductive polymer is polypyrrole, polyaniline or polythiophene.

26. The DSSC according to claim 19, wherein the electrolyte layer is a liquid-, gel- or solid-state, and the electrolyte layer comprises an acetonitrile solution containing iodine, lithium iodide and 4-isobutyl pyridine.
